(19) United States
(12) Patent Application Publication
(10) Pub. No.: US 2024/0324398 A1
(43) Pub. Date: Sep. 26, 2024

(54) DISPLAY APPARATUS AND METHOD OF MANUFACTURING THE SAME

(71) Applicant: Samsung Display Co., Ltd., Yongin-si (KR)

(72) Inventors: Yujin Lee, Yongin-si (KR); Meehye Jung, Yongin-si (KR); Bonyong Koo, Yongin-si (KR)

(21) Appl. No.: 18/480,376

(22) Filed: Oct. 3, 2023

(30) Foreign Application Priority Data
Mar. 24, 2023 (KR) 10-2023-0039235
Apr. 21, 2023 (KR) 10-2023-0052983

(51) Int. Cl. H10K 59/80; H10K 59/12; H10K 59/122; H10K 59/131

(52) U.S. Cl. CPC H10K 59/80522; H10K 59/1201; H10K 59/122; H10K 59/131; H10K 71/60

(57) ABSTRACT

There is provided a display apparatus, wherein the display apparatus includes a substrate, an organic insulating layer on the substrate and having a hole, a subpixel electrode on the organic insulating layer, an auxiliary electrode comprising at least a portion arranged in the hole of the organic insulating layer, a subpixel-defining layer on the organic insulating layer and having a first opening overlapping the auxiliary electrode and a second opening overlapping the subpixel electrode, an emission layer on the subpixel electrode, an opposite electrode on the emission layer, a common layer arranged between the subpixel electrode and the opposite electrode and extending onto the subpixel-defining layer to overlap the subpixel-defining layer, and a spacer below the common layer and overlapping a portion of the auxiliary electrode, a portion of the hole of the organic insulating layer, and a portion of the subpixel-defining layer.

### CROSS-REFERENCE TO RELATED APPLICATIONS

This application claims priority to and the benefit of Korean Patent Application No. 10-2023-0039235, filed on Mar. 24, 2023, and Korean Patent Application No. 10-2023-0052983, filed on Apr. 21, 2023, in the Korean Intellectual Property Office, the entire disclosures of which are incorporated by reference herein.

### BACKGROUND

### 1. Field

One or more embodiments relate to a display apparatus.

### 2. Description of the Related Art

Display apparatuses receive an input of information about an image and

display the image. When display apparatuses are enlarged, while a current propagates to a place far from the current's point of introduction (e.g., to a central region of the display apparatus), a voltage drop occurs due to resistance of cathode electrodes, which may cause a difference in luminance between an outer region and a central region. Furthermore, trenches for discharging gas generated from an organic film arranged in display apparatuses can cause resistance of cathode electrodes to increase, which may intensify a difference in luminance. This background section is provided only to provide background information relating to the present disclosure, and statements made in this background section are not admissions of prior art.

### SUMMARY

One or more embodiments include a display apparatus in which a cathode electrode may be coupled (e.g., connected) to a current source even in a central region of the display apparatus. However, the above aspect is only an example, and aspects of the present disclosure are not limited to the aspect above. According to one or more embodiments of the present disclosure, a display apparatus includes an auxiliary electrode that may be utilized to reduce deterioration of luminance caused by voltage drop.

Additional aspects will be set forth in part in the description which follows and, in part, will be apparent from the description, or may be learned by practice of the presented embodiments of the disclosure.

According to one or more embodiments, a display apparatus includes a substrate, an organic insulating layer on the substrate and having a hole, a subpixel electrode on the organic insulating layer, an auxiliary electrode including at least a portion arranged in the hole of the organic insulating layer, a subpixel-defining layer on the organic insulating layer and having a first opening overlapping the auxiliary electrode and a second opening overlapping the subpixel electrode, an emission layer on the subpixel electrode, an opposite electrode on the emission layer, a common layer arranged between the subpixel electrode and the opposite electrode and extending onto the subpixel-defining layer to overlap the subpixel-defining layer, and a spacer below the common layer and overlapping a portion of the auxiliary electrode, a portion of the hole of the organic insulating layer, and a portion of the subpixel-defining layer.

In an embodiment, the display apparatus may further include an auxiliary wire below the organic insulating layer and electrically coupled (e.g., electrically connected) with the auxiliary electrode.

The auxiliary electrode and the subpixel electrode may include (e.g., may be) a same material.

The subpixel-defining layer may include a tip protruding toward the first opening.

The spacer may cover a portion of the tip and may include a side surface tapered with respect to an upper surface of the auxiliary electrode.

The common layer may include separate portions around another portion of the tip on an opposite side of the hole from the spacer.

One of the separate portions of the common layer may be in direct contact with a portion of the auxiliary electrode.

The opposite electrode may include separate portions around another portion of the tip on an opposite side of the hole from the spacer.

One of the separate portions of the opposite electrode may be in direct contact with a portion of the auxiliary electrode, around the other portion of the tip.

The side surface of the spacer may form an inclination angle of 30 degrees to 60 degrees with respect to the upper surface of the auxiliary electrode.

The organic insulating layer may further include a recess under the tip on an opposite side of the spacer and recessed with respect to a side surface of the organic insulating layer.

An upper surface of a portion of the subpixel-defining layer including the tip may have a step difference with respect to an upper surface of another portion of the subpixel-defining layer on an upper surface of the organic insulating layer.

The subpixel-defining layer may include (e.g., may be) an inorganic insulating material.

The spacer may include (e.g., may be) an organic insulating material.

According to one or more embodiments, a method of manufacturing a display apparatus includes forming a substrate, forming, on the substrate, an organic insulating layer having a hole, forming a subpixel electrode on the organic insulating layer, forming an auxiliary electrode including at least a portion arranged in the hole of the organic insulating layer, forming, on the organic insulating layer, a subpixel-defining layer having a first opening overlapping the auxiliary electrode and a second opening overlapping the subpixel electrode, forming a spacer overlapping a portion of the auxiliary electrode, a portion of the hole of the organic insulating layer, and a portion of the subpixel-defining layer, forming, on the subpixel electrode, an intermediate layer including an emission layer and a common layer, and forming an opposite electrode on the intermediate layer.

The forming of the subpixel-defining layer may include forming a tip protruding toward the first opening from a point where an upper surface of the organic insulating layer and a side surface of the organic insulating layer facing the hole meet.

In the forming of the spacer, a portion of the spacer may overlap a portion of the tip, and a side surface of the spacer may be tapered with respect to an upper surface of the auxiliary electrode.

In the forming of the common layer, the common layer may include separate portions around another portion of the tip on an opposite side of the hole from the spacer, and in the forming of the opposite electrode, the opposite electrode may include separate portions around the other portion of the tip on the opposite side of the hole from the spacer.

The forming of the organic insulating layer may further include forming a recess under the tip located on an opposite side of the hole from the spacer.

The forming of the subpixel-defining layer may include forming, on the organic insulating layer, a sacrificial layer to overlap the auxiliary electrode, forming the subpixel-defining layer to overlap a portion of the sacrificial layer, and removing the sacrificial layer.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic perspective view of a display apparatus according to an embodiment;

FIG. 2 is an enlarged plan view of a portion of a display region of FIG. 1;

FIG. 3 is a cross-sectional view of a portion of a display apparatus according to an embodiment, and is a cross-sectional view of the display region taken along line III-III′ of FIG. 2;

FIG. 4 is a cross-sectional view of a portion of a display apparatus according to an embodiment, and is a cross-sectional view of the display region taken along line IV-IV′ of FIG. 2;

FIGS. 5A, 5B, 5C, 5D, and 5E are schematic cross-sectional views of a portion of a display apparatus at various stages of a manufacturing process according to an embodiment;

FIG. 6 is a plan view of a portion of a display apparatus according to an embodiment;

FIG. 7 is a cross-sectional view of the display apparatus taken along line VII-VII′ of FIG. 6;

FIG. 8 is a cross-sectional view of the display apparatus taken along line VIII-VIII′ of FIG. 6;

FIG. 9 is a cross-sectional view of the display apparatus taken along line IX-IX′ of FIG. 6;

FIG. 10 is a cross-sectional view of a portion of a display apparatus according to an embodiment;

FIG. 11 is a cross-sectional view of a portion of a display apparatus according to an embodiment; and

FIG. 12 is a cross-sectional view of a portion of a display apparatus according to an embodiment.

### DETAILED DESCRIPTION

Reference will now be made in more detail to embodiments, examples of which are illustrated in the accompanying drawings, wherein like reference numerals refer to like elements throughout the present specification. In this regard, the present embodiments may have different suitable forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As used herein, the use of the term “may,” when describing embodiments of the present disclosure, refers to “one or more embodiments of the present disclosure.” Various suitable modifications may be applied to the present embodiments, and particular embodiments will be illustrated in the drawings and described in the detailed description section. The aspects and features of display apparatuses of the present embodiments, and methods to achieve the same, will be clearer referring to the detailed descriptions below with the drawings. However, the disclosure may be implemented in various suitable forms, not by being limited to the embodiments presented below.

Hereinafter, embodiments will be described in more detail with reference to the accompanying drawings, and in the description with reference to the drawings, the same or corresponding elements are indicated by the same reference numerals and redundant descriptions thereof may not be repeated.

In the following embodiments, it will be understood that although the terms “first,” “second,” etc. may be used herein to describe various elements, these elements should not be limited by these terms. These terms are only used to distinguish one element from another.

In the following embodiments, the expression of singularity in the present specification includes the expression of plurality unless clearly specified otherwise in context.

In the following embodiments, it will be further understood that the terms “comprises” and/or “comprising” used herein specify the presence of stated features or elements, but do not preclude the presence or addition of one or more other features or elements.

In the following embodiments, it will be understood that when a layer, region, or element is referred to as being “formed on” another layer, region, or element, it can be directly or indirectly formed on the other layer, region, or element. In some embodiments, for example, one or more intervening layers, regions, or elements may be present.

Sizes of elements in the drawings may be exaggerated or reduced for convenience of explanation. Because sizes and thicknesses of elements in the drawings may be illustrated as exaggerated or reduced for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present specification, the expression “A and/or B” represents A, B, or A and B. In addition, expressions such as “at least one of A or B,” “at least one of A and B,” “at least one selected from among A and B,” and “at least one selected from a group of A and B” represent A, B, or A and B.

In the following embodiment, it will be understood that when a layer, region, or element is coupled (e.g., connected) to another layer, region, or element, the layers, regions or elements may be directly coupled (e.g., directly connected), and/or may be (e.g., may also be) indirectly coupled (e.g., indirectly connected) via one or more other layers, regions, and/or elements therebetween. For example, in the present specification, when a layer, region, or element is electrically coupled (e.g., electrically connected) to another layer, region, or element, the layers, regions, or elements may be directly electrically coupled (e.g., directly electrically connected) and/or may be (e.g., may also be) indirectly electrically coupled (e.g., indirectly electrically connected) via one or more other layers, regions, and/or elements therebetween.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

As used herein, the term “substantially” and similar terms are used as terms of approximation and not as terms of degree, and are intended to account for the inherent deviations in measured or calculated values that would be recognized by those of ordinary skill in the art. Also, the term “about” and similar terms, when used herein in connection with a numerical value or a numerical range, are inclusive of the stated value and mean within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations, or within +30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

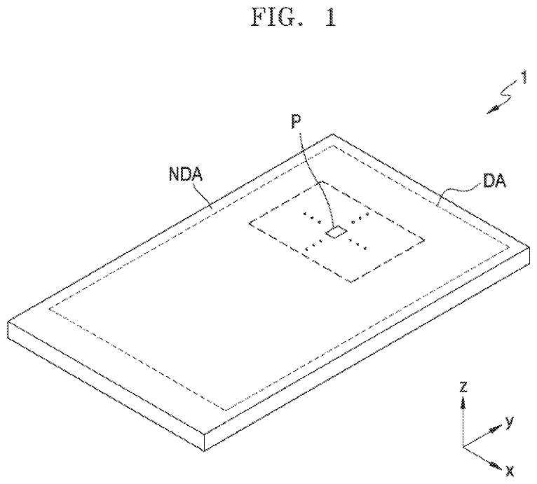

FIG. 1 is a schematic perspective view of a display apparatus according to an embodiment.

Referring to FIG. 1, a display apparatus 1 may include a display region DA and a non-display region NDA located outside of the display region DA. The display region DA may display an image via a subpixel P arranged in the display region DA. In some embodiments, the non-display region NDA is arranged outside of the display region DA, does not display an image, and may entirely surround the display region DA. A driver configured to supply an electrical signal or power to the display region DA may be arranged in the non-display region NDA. A pad that is an area to which electronic devices, printed circuit boards, and the like may be electrically coupled (e.g., electrically connected) may be arranged in the non-display region NDA.

In an embodiment, FIG. 1 illustrates that the display region DA has a polygonal shape (for example, quadrangular shape) in which the length in an x direction is smaller than the length in a y direction, but in another embodiment, the display region DA is a polygonal shape (for example, quadrangular shape) in which the length in the y direction may be smaller than the length in the x direction. FIG. 1 illustrates that the display region DA has a substantially quadrangular shape, but the disclosure is not limited thereto. The display region DA may have various suitable shapes such as a polygon with N sides (N is a natural number of 3 or more), a circle, or an ellipse. FIG. 1 illustrates that a corner portion of the display region DA has a shape including a vertex where two straight lines meet, but in another embodiment, the display region DA may have a polygonal shape with curved corner portions.

Hereinafter, for convenience of explanation, a case in which the display apparatus 1 is an electronic device such as a smartphone is described, but the display apparatus 1 of the disclosure is not limited thereto. The display apparatus 1 may be used in various suitable products such as televisions, laptops, monitors, billboards, or Internet of Things (IOTs) as well as portable electronic devices such as mobile phones, smart phones, tablet personal computers (tablet PCs), mobile communication terminals, electronic notebooks, e-books, portable multimedia players (PMPs), navigations, or ultra-mobile PCs (UMPCs). In addition, the display apparatus 1 according to an embodiment may be used in wearable devices such as smart watches, watch phones, glass-type displays, and head mounted displays (HMDs). In addition, the display apparatus 1 according to an embodiment may be used as a vehicle's dash board, a center information display (CID) located at a vehicle's center fascia or dashboard, a room mirror display covering for a vehicle's side-view mirror, or a display screen, which is located at the back of a front seat, as entertainment for a passenger in a back seat of a vehicle.

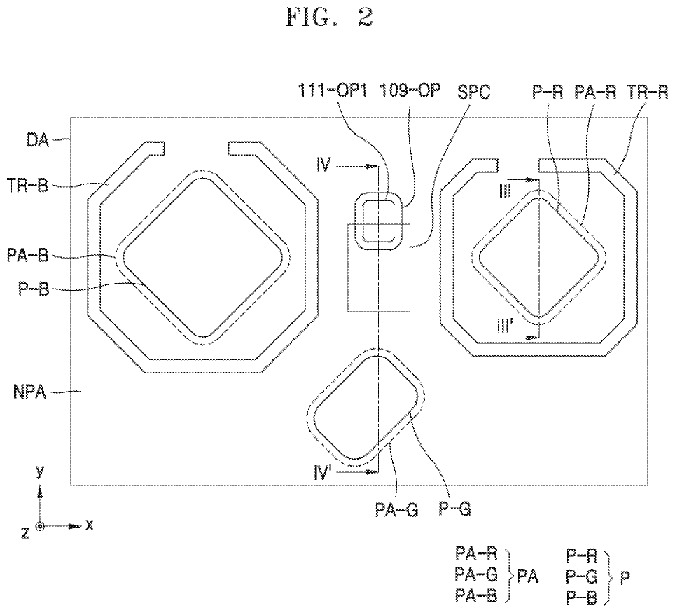

FIG. 2 is an enlarged plan view of a portion of the display region DA of FIG. 1.

Referring to FIG. 2, the display region DA may include a subpixel region PA and a non-subpixel region NPA. The subpixel region PA may be where the subpixel P is arranged and a light-emitting diode is arranged. The non-subpixel region NPA may be arranged around the subpixel region PA and may entirely surround each subpixel region PA.

The subpixel P may include a red subpixel P-R, a green subpixel P-G, and a blue subpixel P-B. The subpixel region PA may include a red subpixel region PA-R, a green subpixel region PA-G, and a blue subpixel region PA-B. FIG. 2 illustrates the subpixel and the subpixel region, each corresponding to each of a red color, a green color, and a blue color, but the disclosure is not limited thereto. In another embodiment, the display region DA may include the subpixel P and the subpixel region PA, each corresponding to each of a red color, a green color, a blue color, and a white color.

FIG. 2 illustrates that each of the subpixel P and the subpixel region PA has a quadrangular shape with rounded corners, but the disclosure is not limited thereto. In another embodiment, each of the subpixel P and the subpixel region PA may have various suitable shapes such as a polygon with N sides (N is a natural number of 3 or more) or an ellipse.

A trench may be arranged around at least one subpixel region selected from among the red subpixel region PA-R, the green subpixel region PA-G, and the blue subpixel region PA-B.

For example, a first trench TR-R may be arranged in the non-subpixel region NPA around the red subpixel region PA-R. A second trench TR-B may be arranged in the non-subpixel region NPA around the blue subpixel region PA-B. The first trench TR-R may partially surround the red subpixel region PA-R. For example, one side surface of the first trench TR-R may be open without completely surrounding the red subpixel region PA-R. The second trench TR-B may partially surround the blue subpixel region PA-B. For example, one side surface of the second trench TR-B may be open without completely surrounding the blue subpixel region PA-B.

FIG. 2 illustrates that the shape of each of the first trench TR-R and the second trench TR-B is substantially an octagon with one side open, but the disclosure is not limited thereto. In another embodiment, each of the first trench TR-R and the second trench TR-B may have various suitable shapes such as a polygon with N sides (N is a natural number of 3 or more) or an ellipse. FIG. 2 illustrates that a trench is not arranged around the green subpixel region PA-G, but the disclosure is not limited thereto. In another embodiment, a trench may be arranged to correspond to at least one of the red subpixel region PA-R, the green subpixel region PA-G, or the blue subpixel region PA-B.

A hole 109-OP of a second organic insulating layer and a first opening 111-OP1 of a subpixel-defining layer may be arranged in the non-subpixel region NPA. A spacer SPC may be arranged to overlap a portion of the hole 109-OP of the second organic insulating layer and a portion of the first opening 111-OP1 of the subpixel-defining layer, in the non-subpixel region NPA.

FIG. 2 illustrates that the hole 109-OP of the second organic insulating layer, the first opening 111-OP1 of the subpixel-defining layer, and the spacer SPC are arranged between the red subpixel region PA-R and the blue subpixel region PA-B, but the disclosure is not limited thereto. In another embodiment, the hole 109-OP of the second organic insulating layer, the first opening 111-OP1 of the subpixel-defining layer, and the spacer SPC may be arranged in the non-subpixel region NPA without limitation, for example, on a left or right side of the green subpixel region PA-G.

FIG. 2 illustrates that the shape of each of the hole 109-OP of the second organic insulating layer and the first opening 111-OP1 of the subpixel-defining layer is a quadrangle with rounded corners, and the shape of the spacer SPC is a quadrangle, but the disclosure is not limited thereto. In another embodiment, the hole 109-OP of the second organic insulating layer, the first opening 111-OP1 of the subpixel-defining layer, and the spacer SPC may each have various suitable shapes such as a polymer with N sides (N is a natural number of 3 or more) or an ellipse.

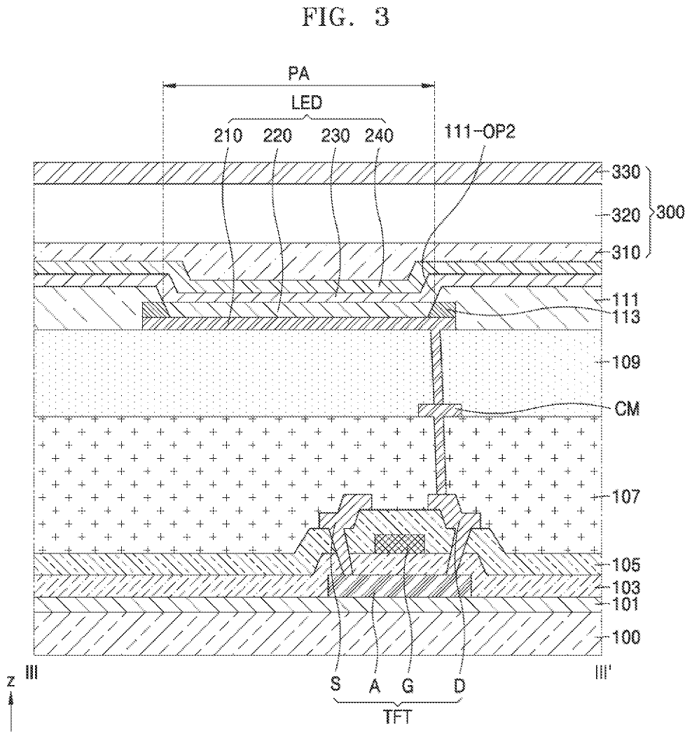

FIG. 3 is a cross-sectional view of a portion of a display apparatus according to an embodiment, and is a cross-sectional view of the display region taken along line III-III′ of FIG. 2.

Referring to FIG. 3, a light-emitting diode LED corresponding to a subpixel arranged in a display region may be disposed over a substrate 100. The light-emitting diode LED may be electrically coupled (e.g., electrically connected) to a thin-film transistor TFT.

The thin-film transistor TFT may include an activation layer A, a gate electrode G overlapping a partial region of the activation layer A, and a source electrode S and a drain electrode D, each coupled (e.g., connected) to the activation layer A. The gate electrode G includes (e.g., is) at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layered or multilayer structure including (e.g., being) the above-described material.

A buffer layer 101 may be arranged between the activation layer A and the substrate 100 to prevent or block penetration of impurities. A gate insulating layer 103 may be arranged between the activation layer A and the gate electrode G. An interlayer insulating layer 105 may be disposed on the gate electrode G. Each of the buffer layer 101, the gate insulating layer 103, and the interlayer insulating layer 105 may include (e.g., may be) an inorganic insulating material such as silicon oxide, silicon nitride, silicon oxynitride, aluminum oxide, aluminum nitride, titanium oxide, and/or titanium nitride.

The source electrode S and the drain electrode D may be disposed on the interlayer insulating layer 105 and may be coupled (e.g., connected) to the activation layer A through a contact hole formed in the interlayer insulating layer 105 and the gate insulating layer 103. For example, the source electrode S may be coupled (e.g., connected) to the activation layer A through a first contact hole in the interlayer insulation layer 105 and in the gate insulating layer 103, and the drain electrode D may be coupled (e.g., connected) to the activation layer A through a second contact hole in the interlay insulation layer 105 and in the gate insulating layer 103. Each of the source electrode S and the drain electrode D may include (e.g., may be) at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), or copper (Cu), and may be formed as a single layer or a multilayer.

A first organic insulating layer 107 may be disposed on the thin-film transistor TFT. The first organic insulating layer 107 may include (e.g., may be) an organic insulating material such as acryl, benzocyclobutene (BCB), polyimide (PI), and/or hexamethyldisiloxane (HMDSO).

A contact metal CM may be disposed on the first organic insulating layer 107. The contact metal CM may include (e.g., may be) aluminum (Al), copper (Cu), and/or titanium (Ti), and may be formed as a single layer or a multilayer, each including (e.g., being) the above-described material.

A second organic insulating layer 109 may be arranged between the contact metal CM and a subpixel electrode 210. The second organic insulating layer 109 may include (e.g., may be) an organic insulating material such as acryl, BCB, PI, and/or HMDSO. According to an embodiment described with reference to FIG. 3, it is illustrated that the thin-film transistor TFT and the subpixel electrode 210 are electrically coupled (e.g., electrically connected) with each other via the contact metal CM, but according to another embodiment, the contact metal CM may be omitted, and one organic insulating layer may be arranged between the thin-film transistor TFT and the subpixel electrode 210. In some embodiments, at least three organic insulating layers may be arranged between the thin-film transistor TFT and the subpixel electrode 210, and the thin-film transistor TFT and the subpixel electrode 210 may be electrically coupled (e.g., electrically connected) with each other via a plurality of contact metals.

The subpixel electrode 210 may be disposed on the second organic insulating layer 109. The subpixel electrode 210 may be formed to be a transparent/semi-transparent electrode or a reflective electrode. When the subpixel electrode 210 is formed as a transparent/semi-transparent electrode, the subpixel electrode 210 may include (e.g., may be), for example, indium tin oxide (ITO), indium zinc oxide (IZO), zinc oxide (ZnO), indium oxide (In₂O₃), indium gallium oxide (IGO), and/or aluminum zinc oxide (AlZO). When the subpixel electrode 210 is formed as a reflective electrode, silver (Ag), magnesium (Mg), aluminum (Al), platinum (Pt), palladium (Pd), gold (Au), nickel (Ni), neodymium (Nd), iridium (Ir), chromium (Cr), and/or a compound thereof may be used to form a reflective film, and a film including (e.g., being) ITO, IZO, ZnO, and/or In₂O₃ may be formed on the reflective film. In an embodiment, the subpixel electrode 210 may have a structure in which an ITO layer, an Ag layer, and an ITO layer are sequentially stacked. The disclosure is not limited thereto, and the subpixel electrode 210 may include (e.g., may be) various suitable materials and may have a single-layered or multilayer structure, and various suitable modifications may be made. The subpixel electrode 210 may be electrically coupled (e.g., electrically connected) to the contact metal CM via a contact hole formed in the second organic insulating layer 109.

A subpixel-defining layer 111 may cover an edge region (or edge) of the subpixel electrode 210. The subpixel-defining layer 111 may include a second opening 111-OP2 exposing a portion of the subpixel electrode 210. The second opening 111-OP2 of the subpixel-defining layer 111 may correspond to a region from which light of the light-emitting diode LED is emitted, and may define an emission region of the subpixel P or the light-emitting diode LED.

A passivation layer 113 may be arranged between the subpixel electrode 210 and the subpixel-defining layer 111. The passivation layer 113 may have an opening overlapping the subpixel electrode 210. The passivation layer 113 may include (e.g., may be) a conductive oxide such as ITO, IZO, indium gallium zinc oxide (IGZO), indium tin zinc oxide (ITZO), ZnO, aluminum-doped zinc oxide (AZO), gallium-doped zinc oxide (GZO), zinc tin oxide (ZTO), gallium tin oxide (GTO), and/or fluorine-doped tin oxide (FTO).

An emission layer 220 may be disposed on the subpixel electrode 210. The emission layer 220 may include an organic emission layer including (e.g., being) a low-molecular-weight and/or polymer material.

An opposite electrode 240 may be disposed on the emission layer 220. The opposite electrode 240 may be formed as a transparent/semi-transparent electrode. When the opposite electrode 240 is formed as a transparent/semi-transparent electrode, the opposite electrode 240 may include (e.g., may be) at least one material selected from among Ag, Al, Mg, Li, Ca, Cu, LiF/Ca, LiF/AI, MgAg, and CaAg, and may be formed in the form of a thin film having a thickness of several to several tens of nanometers (nm). The configuration and material of the opposite electrode 240 are not limited thereto, and various suitable modifications may be made.

A common layer 230 may be arranged between the subpixel electrode 210 and the opposite electrode 240. The common layer 230 may have a structure in which a hole injection layer (HIL), a hole transport layer (HTL), and/or the like are stacked in a single or complex structure. FIG. 3 illustrates that the common layer 230 is disposed on the emission layer 220, but the disclosure is not limited thereto. In another embodiment, the common layer 230 may be disposed under the emission layer 220 (e.g., between the emission layer 220 and the subpixel electrode 210) and may include an electron transport layer (ETL) and/or an electron injection layer (EIL). In another embodiment, the common layer 230 may be disposed both under and above the emission layer 220. For example, the common layer 230 may be both between the emission layer 220 and the subpixel electrode 210 and may also be between the emission layer 220 and the opposite electrode 240.

An encapsulation layer 300 may be disposed on the opposite electrode 240. The encapsulation layer 300 may include at least one inorganic encapsulation layer and at least one organic encapsulation layer. For example, the encapsulation layer 300 may include a first inorganic encapsulation layer 310, a second inorganic encapsulation layer 330, and an organic encapsulation layer 320 therebetween. Each of the first and second inorganic encapsulation layers 310 and 330 may include (e.g., may be) an inorganic insulating material such as silicon oxide, silicon nitride, and/or silicon oxynitride, and the organic encapsulation layer 320 may include (e.g., may be) at least one organic insulating material selected from among polyethyleneterephthalate, polyethylenenaphthalate, polycarbonate, polyimide, polyethylenesulfonate, polyoxymethylene, polyarylate, and hexamethyldisiloxane.

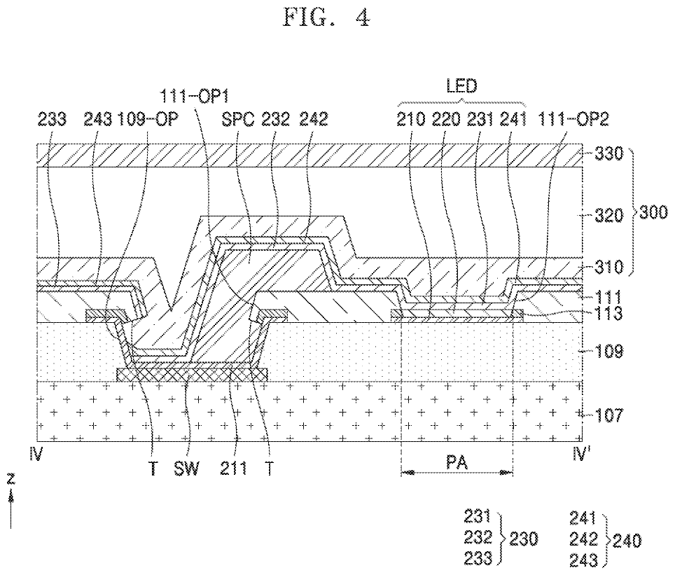

FIG. 4 is a cross-sectional view of a portion of a display apparatus according to an embodiment, and is a cross-sectional view of the display region taken along line IV-IV′ of FIG. 2.

An auxiliary wire SW may be disposed on the first organic insulating layer 107. The auxiliary wire SW may be electrically coupled (e.g., electrically connected) with an auxiliary electrode 211. The auxiliary wire SW may be electrically coupled (e.g., electrically connected) to the opposite electrode 240 via the auxiliary electrode 211. The auxiliary wire SW may provide a common voltage to the opposite electrode 240.

The second organic insulating layer 109 may be disposed on the first organic insulating layer 107. The second organic insulating layer 109 may include the hole 109-OP overlapping the auxiliary wire SW. The width of the smallest portion of the hole 109-OP of the second organic insulating layer 109 may be smaller than the width of the auxiliary wire SW. For example, a smallest width of the hole 109-OP (e.g., a smallest width of the hole 109-OP along a direction perpendicular to the z-axis direction) may be smaller than a width (e.g., a width along the same direction perpendicular to the z-axis direction) of the auxiliary wire SW. An edge of the auxiliary wire SW may be covered by the second organic insulating layer 109. The second organic insulating layer 109 may include a side surface tapered with respect to an upper surface of the auxiliary wire SW.

FIG. 4 illustrates that the auxiliary wire SW is disposed on the first organic insulating layer 107 and the hole 109-OP is formed in the second organic insulating layer 109, but the disclosure is not limited thereto. In another embodiment, the auxiliary wire SW may be disposed under the first organic insulating layer 107 and may be arranged to overlap a hole penetrating the first organic insulating layer 107 and the second organic insulating layer 109.

At least a portion of the auxiliary electrode 211 may be arranged in the hole 109-OP of the second organic insulating layer 109. The auxiliary electrode 211 is disposed on the second organic insulating layer 109 and may be electrically coupled (e.g., electrically connected) with the auxiliary wire SW via the hole 109-OP of the second organic insulating layer 109. The auxiliary electrode 211 may be in direct contact with the auxiliary wire SW. For example, a lower surface of the auxiliary electrode 211 may be in direct contact with the upper surface of the auxiliary wire SW. The auxiliary electrode 211 may include (e.g., may be) a material that is the same as that of the subpixel electrode 210. The auxiliary electrode 211 and the subpixel electrode 210 may include (e.g., may be) a same material. The auxiliary electrode 211 and the subpixel electrode 210 may be the same in material.

A portion of the passivation layer 113 may be disposed on the auxiliary electrode 211. The passivation layer 113 disposed on the auxiliary electrode 211 may be disposed on an edge region (or edge) of the auxiliary electrode 211. Other characteristics of the passivation layer 113 may be the same as those described above with reference to FIG. 3.

The subpixel electrode 210 may be disposed on the second organic insulating layer 109. A portion of the passivation layer 113 may be disposed on the edge region (or edge) of the subpixel electrode 210. The emission layer 220 may be disposed on the subpixel electrode 210.

The subpixel-defining layer 111 may be disposed on the second organic insulating layer 109. The subpixel-defining layer 111 may include the first opening 111-OP1 overlapping the auxiliary electrode 211 and the second opening 111-OP2 overlapping the subpixel electrode 210. The first opening 111-OP1 of the subpixel-defining layer 111 may overlap the hole 109-OP of the second organic insulating layer 109. The width of the first opening 111-OP1 of the subpixel-defining layer 111 may be smaller than the width of the largest portion of the hole 109-OP of the second organic insulating layer 109. For example, a width (e.g., a width along a direction perpendicular to the z-axis direction) of the first opening 111-OP1 may be smaller than a largest width (e.g., a largest width along the same direction perpendicular to the z-axis direction) of the hole 109-OP. The second opening 111-OP2 of the subpixel-defining layer 111 may expose a portion of the subpixel electrode 210.

A portion of the subpixel-defining layer 111 may include a tip T protruding toward the first opening 111-OP1 of the subpixel-defining layer 111. For example, the subpixel-defining layer 111 may include the tip T protruding toward the first opening 111-OP1 of the subpixel-defining layer 111 from a point where an upper surface of the second organic insulating layer 109 and the side surface of the second organic insulating layer 109 facing (e.g., defining at least part of) the hole 109-OP of the second organic insulating layer 109 meet. For example, the portion of the subpixel-defining layer 111 that defines the tip T may extend over part (e.g., overlap part) of the first opening 111-OP1 in the plan view. The subpixel-defining layer 111 may include (e.g., may be) an inorganic insulating material.

The spacer SPC may be disposed below the common layer 230. The spacer SPC may have an isolated shape as shown in FIG. 2 and may overlap a portion of the auxiliary electrode 211, a portion of the hole 109-OP of the second organic insulating layer 109, and a portion of the subpixel-defining layer 111 as shown in FIG. 4.

The spacer SPC may cover a portion of the auxiliary electrode 211. For example, the spacer SPC may cover a portion of an upper surface and one side surface of the auxiliary electrode 211. For example, the spacer SPC may be on (e.g., directly on) an upper surface of a portion of the auxiliary electrode 211 that is on (e.g., directly on) the auxiliary wire SW, and on a side surface of the auxiliary electrode 211 that extends from the upper surface of the auxiliary electrode 211 and away from the auxiliary wire SW. The spacer SPC may cover a portion of the tip T of the subpixel-defining layer 111.

The spacer SPC may include a side surface tapered with respect to the upper surface of the auxiliary electrode 211. One side surface of the spacer SPC may form an angle (e.g., a smallest angle) of about 30 degrees to about 60 degrees with respect to the upper surface of the auxiliary electrode 211. For example, one side surface of the spacer SPC may form an angle of about 50 degrees with respect to the upper surface of the auxiliary electrode 211. In some embodiments, an interior angle of the spacer SPC (e.g., an angle extending only through the spacer SPC) may be formed between the one side surface of the spacer SPC and a lower surface of the spacer SPC facing the auxiliary electrode 211, and the interior angle may be about 30 degrees to about 60 degrees. The spacer SPC may prevent the opposite electrode 240 from being separated, or may reduce the likelihood of such separation, when the common layer 230 and the opposite electrode 240 are deposited on the spacer SPC, by providing a gentle slope.

The spacer SPC may include (e.g., may be) an organic insulating material. For example, the spacer SPC may include (e.g., may be) a photosensitive organic insulating material.

The common layer 230 may be arranged to overlap the emission layer 220, the subpixel-defining layer 111, the auxiliary electrode 211, and the spacer SPC. For example, the common layer 230 may be arranged on the emission layer 220 (or under the emission layer 220) and may extend onto the subpixel-defining layer 111 to overlap the subpixel-defining layer 111. The common layer 230 may include a first portion 231 overlapping the subpixel electrode 210, a second portion 232 partially overlapping the auxiliary electrode 211 and/or the spacer SPC, and a third portion 233 disposed on a portion of the subpixel-defining layer 111 on an opposite side of the spacer SPC (e.g., an opposite side of the first opening 111-OP1 from a side that the spacer SPC is on).

The second portion 232 of the common layer 230 may be a portion of the first portion 231. For example, the second portion 232 of the common layer 230 may correspond to a portion of the first portion 231 extending toward the spacer SPC. In some embodiments, the second portion 232 of the common layer 230 may be integral with the first portion 231. For example, the second portion 232 may extend from the first portion 231.

The second portion 232 of the common layer 230 may be disposed on the auxiliary electrode 211 and the spacer SPC. In some embodiments, the second portion 232 of the common layer 230 may cover a portion of the auxiliary electrode 211 and the spacer SPC. The second portion 232 of the common layer 230 may be in direct contact with a portion of the auxiliary electrode 211 and the spacer SPC. A portion of the upper surface of the auxiliary electrode 211 arranged in the hole 109-OP of the second organic insulating layer 109, for example, the portion not overlapping the spacer SPC, may be covered by the second portion 232 of the common layer 230. In some embodiments, the upper surface of the auxiliary electrode 211 arranged in the hole 109-OP of the second organic insulating layer 109 may be covered by the second portion 232 of the common layer 230 and the spacer SPC.

The third portion 233 of the common layer 230 may be disposed on the subpixel-defining layer 111 on the opposite side of the spacer SPC. A portion of the third portion 233 of the common layer 230 may be disposed on the tip T of the subpixel-defining layer 111.

The second portion 232 and the third portion 233 of the common layer 230 may be separated from each other on the opposite side of the spacer SPC. For example, the second portion 232 and the third portion 233 of the common layer 230 may be separated and apart from each other by the tip T of the subpixel-defining layer 111 on the opposite side of the spacer SPC during a deposition process.

The opposite electrode 240 may be disposed on the common layer 230. The opposite electrode 240 may include a first portion 241 partially overlapping the subpixel electrode 210, a second portion 242 partially overlapping the auxiliary electrode 211 and/or the spacer SPC, and a third portion 243 disposed on a portion of the subpixel-defining layer 111 facing the spacer SPC. In some embodiments, the third portion 243 is on a portion of the subpixel-defining layer 111 at an opposite side of the first opening 111-OP1 from the spacer SPC.

The second portion 242 of the opposite electrode 240 may be a portion of the first portion 241. For example, the second portion 242 of the opposite electrode 240 may correspond to a portion of the first portion 241 extending toward the spacer SPC. In some embodiments, the second portion 242 of the opposite electrode 240 may be integral with the first portion 241. For example, the second portion 242 may extend from the first portion 241.

The second portion 242 of the opposite electrode 240 may overlap the second portion 232 of the common layer 230. The second portion 242 of the opposite electrode 240 may be in direct contact with a portion of the auxiliary electrode 211 arranged in the hole 109-OP of the second organic insulating layer 109.

The second portion 242 of the opposite electrode 240 may be in direct contact with a portion of the auxiliary electrode 211 on the opposite side of the spacer SPC. In some embodiments, a material forming the opposite electrode 240 may be deposited in a direction oblique to a direction (for example, z direction) normal (e.g., perpendicular) to the substrate 100, and accordingly, the second portion 242 of the opposite electrode 240 may further extend beyond an edge of the second portion 232 of the common layer 230 and may be in direct contact with a portion of the auxiliary electrode 211. For example, the second portion 242 may directly contact a side surface of the auxiliary electrode 211 that extends from an upper surface of a portion of the auxiliary electrode 211 that is on (e.g., directly on) the auxiliary wire SW, and that extends away from the auxiliary wire SW. A contact region between a portion of the opposite electrode 240 and a portion of the auxiliary electrode 211 may be disposed near the tip T, for example, under the tip T.

The opposite electrode 240 may be electrically coupled (e.g., electrically connected) with the auxiliary electrode 211 via the second portion 242. The auxiliary electrode 211 may be electrically coupled (e.g., electrically connected) with the auxiliary wire SW. The opposite electrode 240 may receive a common voltage via the auxiliary electrode 211 and the auxiliary wire SW.

The third portion 243 of the opposite electrode 240 may overlap the third portion 233 of the common layer 230. A portion of the third portion 243 of the opposite electrode 240 may be disposed on the tip T of the subpixel-defining layer 111.

The second portion 242 and the third portion 243 of the opposite electrode 240 may be separated from each other on the opposite side of the spacer SPC (e.g., at an opposite side of the first opening 111-OP1 from the spacer SPC). For example, the second portion 242 and the third portion 243 of the opposite electrode 240 may be separated and apart from each other by the tip T of the subpixel-defining layer 111 facing the spacer SPC during a deposition process.

The encapsulation layer 300 may be disposed on the opposite electrode 240.

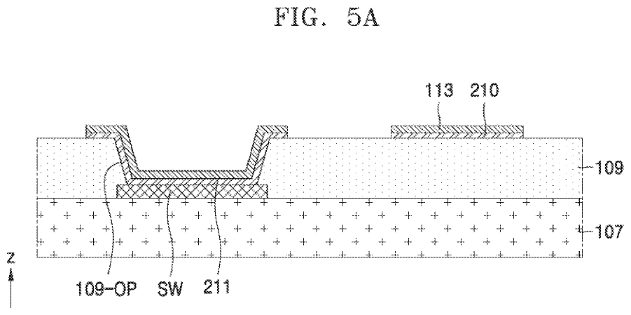

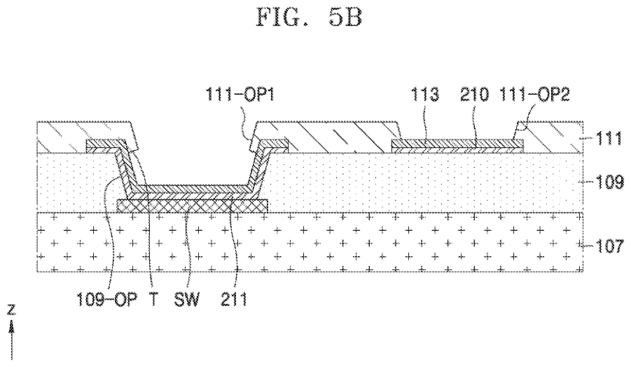

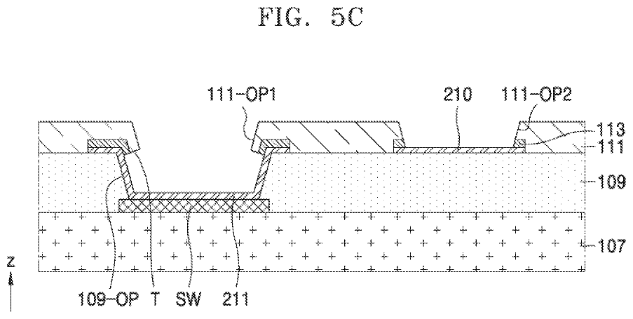

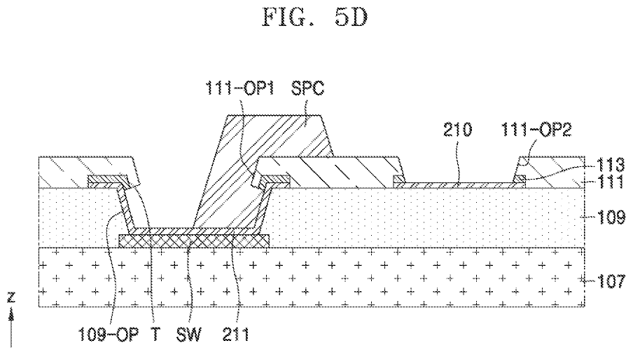

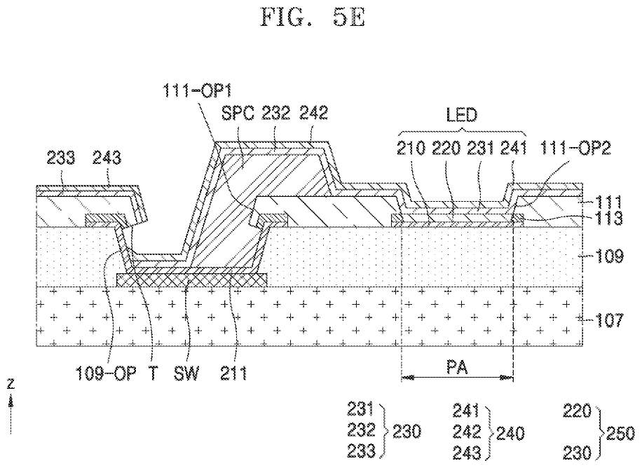

FIGS. 5A to 5E are schematic cross-sectional views of a portion of a display apparatus at various stages of a manufacturing process according to an embodiment.

Referring to FIG. 5A, the auxiliary wire SW and the second organic insulating layer 109 may be disposed on the first organic insulating layer 107.

The second organic insulating layer 109 may include the hole 109-OP overlapping the auxiliary wire SW. An edge of the auxiliary wire SW may overlap the second organic insulating layer 109.

The subpixel electrode 210 and the auxiliary electrode 211 may be disposed on the second organic insulating layer 109. At least a portion of the auxiliary electrode 211 may be arranged in the hole 109-OP of the second organic insulating layer 109. The subpixel electrode 210 and the auxiliary electrode 211 may include (e.g., may be) the same material and may be formed concurrently (e.g., simultaneously).

The auxiliary electrode 211 is disposed on the second organic insulating layer 109 and may be electrically coupled (e.g., electrically connected) with the auxiliary wire SW via the hole 109-OP of the second organic insulating layer 109. The auxiliary electrode 211 may be in direct contact with the auxiliary wire SW. For example, a lower surface of the auxiliary electrode 211 may be in direct contact with an upper surface of the auxiliary wire SW. The auxiliary electrode 211 may include (e.g., may be) a material same as that of the subpixel electrode 210.

The passivation layer 113 may be formed on the subpixel electrode 210 and the auxiliary electrode 211. The passivation layer 113 on the subpixel electrode 210 may be patterned together with the subpixel electrode 210, and the passivation layer 113 on the auxiliary electrode 211 may be patterned together with the auxiliary electrode 211. The passivation layer 113 may include (e.g., may be) a conductive oxide such as ITO.

Referring to FIG. 5B, the subpixel-defining layer 111 may be formed on the subpixel electrode 210 and the auxiliary electrode 211.

The subpixel-defining layer 111 may include the first opening 111-OP1 overlapping the auxiliary electrode 211 and the second opening 111-OP2 overlapping the subpixel electrode 210. An edge of each of the subpixel electrode 210 and the auxiliary electrode 211 may overlap the subpixel-defining layer 111.

The first opening 111-OP1 of the subpixel-defining layer 111 may overlap the hole 109-OP of the second organic insulating layer 109.

A portion of the passivation layer 113 disposed on the auxiliary electrode 211 may be exposed via the first opening 111-OP1 of the subpixel-defining layer 111. A portion of the passivation layer 113 disposed on the subpixel electrode 210 may be exposed via the second opening 111-OP2 of the subpixel-defining layer 111. In a process for forming the first opening 111-OP1 and the second opening 111-OP2 of the subpixel-defining layer 111 by etching a portion of the subpixel-defining layer 111, the passivation layer 113 may protect the auxiliary electrode 211 and the subpixel electrode 210.

In a process for forming the first opening 111-OP1 of the subpixel-defining layer 111, a portion of the subpixel-defining layer 111 may include the tip T protruding toward the first opening 111-OP1 of the subpixel-defining layer 111. For example, the subpixel-defining layer 111 may include the tip T protruding toward the first opening 111-OP1 of the subpixel-defining layer 111 from a point where an upper surface of the second organic insulating layer 109 and a side surface of the second organic insulating layer 109 facing (e.g., defining at least part of) the hole 109-OP meet.

Referring to FIG. 5C, a portion of the passivation layer 113 may be etched.

After the etching, the passivation layer 113 remaining on the auxiliary electrode 211 may cover an edge region (or edge) of the auxiliary electrode 211, and the passivation layer 113 remaining on the subpixel electrode 210 may cover an edge region (or edge) of the subpixel electrode 210. After the etching, a remaining portion of the passivation layer 113 may be arranged between the auxiliary electrode 211 and the subpixel-defining layer 111. After the etching, a remaining portion of the passivation layer 113 may be arranged between the subpixel electrode 210 and the subpixel-defining layer 111.

An upper surface of the passivation layer 113 covering the edge region (or edge) of the auxiliary electrode 211 may be covered by the tip T of the subpixel-defining layer 111.

Referring to FIG. 5D, the spacer SPC may be formed on the auxiliary electrode 211 and the subpixel-defining layer 111.

The spacer SPC may be arranged to overlap a portion of the auxiliary electrode 211, a portion of the hole 109-OP of the second organic insulating layer 109, and a portion of the subpixel-defining layer 111. The spacer SPC may include a side surface tapered with respect to an upper surface of the auxiliary electrode 211. The side surface of the spacer SPC may form an angle of 30 degrees to 60 degrees with respect to the upper surface of the auxiliary electrode 211.

Referring to FIG. 5E, an intermediate layer 250 including the emission layer 220 and the common layer 230 may be formed on the embodiment shown in FIG. 5D. Afterwards, the opposite electrode 240 may be formed on the intermediate layer 250.

A structure of a stack of the subpixel electrode 210, the emission layer 220, a portion of the common layer 230 overlapping the second opening 111-OP2 of the subpixel-defining layer 111, and a portion of the opposite electrode 240 overlapping the second opening 111-OP2 of the subpixel-defining layer 111 may form the light-emitting diode LED.

Afterwards, the encapsulation layer 300 (see FIG. 4) may be disposed on the embodiment shown in FIG. 5E to implement (e.g., provide) the embodiment shown in FIG. 4.

Among the features of each element of the embodiments shown in FIGS. 5A to 5E, features not mentioned above are the same as those described with reference to FIG. 4.

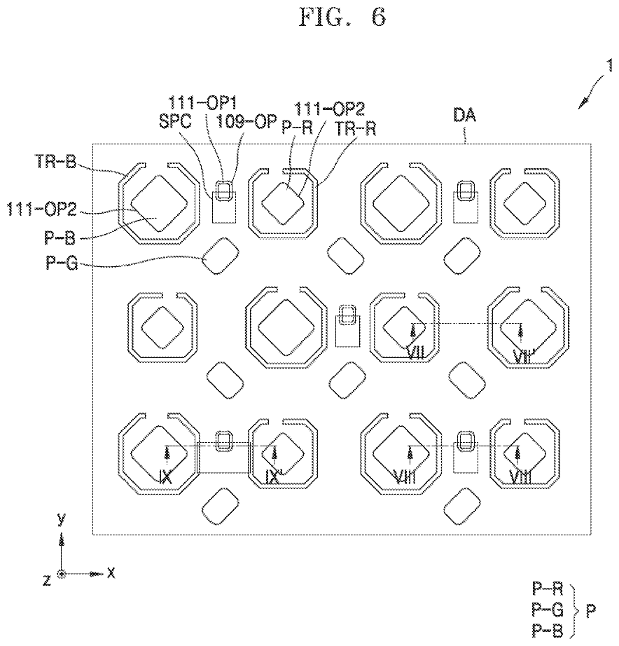

FIG. 6 is a plan view of a portion of a display apparatus according to an embodiment.

The display region DA of the display apparatus 1 may include a plurality of red subpixels P-R, a plurality of green subpixels P-G, a plurality of blue subpixels P-B, a plurality of trenches arranged around at least one subpixel P, at least one hole 109-OP of the second organic insulating layer, at least one first opening 111-OP1 of the subpixel-defining layer, and/or at least one spacer SPC.

In the display region DA, the subpixels P may be two-dimensionally arranged in ±x directions and ±y directions. In an embodiment, an array of the subpixels P may include a plurality of columns (or pixel columns) arranged in the ty directions. Among the subpixels P of different colors, two subpixels P emitting light of different colors, for example, the red subpixel P-R and the blue subpixel P-B, may be arranged in the same column, and the other subpixel P, for example, the green subpixel P-G, may be arranged in another column. The red subpixels P-R and the blue subpixels P-B corresponding to an i^{th} (i is a natural number) column may be alternately arranged while being apart from each other in the ty directions. The green subpixels P-G corresponding to an i+1^{th} column may be apart from each other. The array of the subpixels P may have a structure in which the i^{th} column and the i+1^{th} column are repeated in the ±x directions.

In an embodiment, a distance between neighboring red subpixels P-R in the same column (for example, i^{th} column) and a distance between neighboring blue subpixels P-B in the same column (for example, i^{th} column) may be substantially the same. Distances between neighboring green subpixels P-G in the same column (for example, i+1^{th} column) may be substantially the same.

The hole 109-OP of the second organic insulating layer, the first opening 111-OP1 of the subpixel-defining layer, and the spacer SPC may be arranged between neighboring subpixels P. FIG. 6 illustrates that the hole 109-OP of the second organic insulating layer, the first opening 111-OP1 of the subpixel-defining layer, and the spacer SPC are arranged in a space between the green subpixels P-G in the i+1^{th} column, but the disclosure is not limited thereto. In another embodiment, the hole 109-OP of the second organic insulating layer, the first opening 111-OP1 of the subpixel-defining layer, and the spacer SPC may be arranged in a space between the red subpixel P-R and the blue subpixel P-B in the i^{th} column, and various suitable modifications may be made.

FIG. 6 illustrates that the hole 109-OP of the second organic insulating layer, the first opening 111-OP1 of the subpixel-defining layer, and the spacer SPC are arranged in the ty directions along the same column (for example, i+1^{th} column in which the green subpixel P-G is arranged), but the disclosure is not limited thereto. In another embodiment, when an i^{th} row in which the blue subpixel P-B and the red subpixel P-R are arranged in the ±x directions and an i+1^{th} row in which the green subpixel P-G is arranged in the ±x directions are defined, the hole 109-OP of the second organic insulating layer, the first opening 111-OP1 of the subpixel-defining layer, and the spacer SPC may be arranged in the ±x directions along the i^{th} row and/or the i+1^{th} row, and various suitable modifications may be made.

FIG. 6 illustrates that the spacer SPC is arranged in (e.g., extends from) the −y direction of the hole 109-OP of the second organic insulating layer and the first opening 111-OP1 of the subpixel-defining layer, but the disclosure is not limited thereto. In another embodiment, the spacer SPC may be arranged in (e.g., extend from) the ±x directions or ±y directions of the hole 109-OP of the second organic insulating layer and the first opening 111-OP1 of the subpixel-defining layer.

A trench may be arranged around the subpixel P. For example, the first trench TR-R may be arranged around the red subpixel P-R, and the second trench TR-B may be arranged around the blue subpixel P-B.

A section crossing the first trench TR-R and the second trench TR-B may include a section VII-VII′ in which the hole 109-OP of the second organic insulating layer, the first opening 111-OP1 of the subpixel-defining layer, and the spacer SPC are not arranged. The section crossing the first trench TR-R and the second trench TR-B may include a section VIII-VIII′ in which the hole 109-OP of the second organic insulating layer, the first opening 111-OP1 of the subpixel-defining layer, and the spacer SPC are arranged. The section crossing the first trench TR-R and the second trench TR-B may include a section IX-IX′ in which the spacer SPC overlaps a portion of the first trench TR-R and/or a portion of the second trench TR-B.

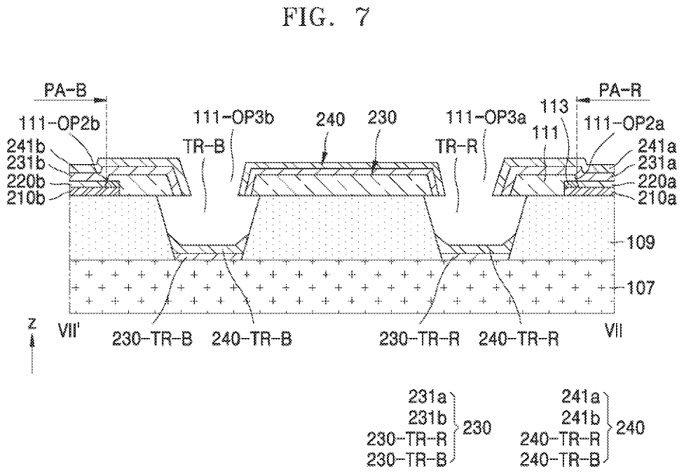

FIG. 7 is a cross-sectional view of the display apparatus taken along line VII-VII′ of FIG. 6.

Referring to FIG. 7, the second organic insulating layer 109 may be disposed on the first organic insulating layer 107. The second organic insulating layer 109 may include the first trench TR-R and the second trench TR-B.

The first trench TR-R and the second trench TR-B may each be a penetration hole penetrating the second organic insulating layer 109. The first trench TR-R and the second trench TR-B may each include a side surface tapered with respect to an upper surface of the first organic insulating layer 107. For example, the first trench TR-R and the second trench TR-B may each have a width that is tapered (e.g., that increases via a taper) in a direction (e.g., the z-axis direction) away from the first organic insulating layer 107.

A first subpixel electrode 210a and a second subpixel electrode 210b may be disposed on the second organic insulating layer 109.

The passivation layer 113 may be disposed on the first subpixel electrode 210a and the second subpixel electrode 210b. The passivation layer 113 may cover an edge region (or edge) of each of the first subpixel electrode 210a and the second subpixel electrode 210b.

A first emission layer 220a may be disposed on the first subpixel electrode 210a. A second emission layer 220b may be disposed on the second subpixel electrode 210b. The first emission layer 220a may emit red light. The second emission layer 220b may emit blue light.

The subpixel-defining layer 111 may be disposed on the second organic insulating layer 109. The subpixel-defining layer 111 may include second-1 and second-2 openings 111-OP2a and 111-OP2b overlapping the first and second subpixel electrodes 210a and 210b. For example, the subpixel-defining layer 111 may include the second-1 opening 111-OP2a overlapping the first subpixel electrode 210a and a second-2 opening 111-OP2b overlapping the second subpixel electrode 210b. The second-1 and second-2 openings 111-OP2a and 111-OP2b of the subpixel-defining layer 111 may respectively expose the first and second emission layers 220a and 220b, and may define the red subpixel P-R and the blue subpixel P-B or an emission region.

The subpixel-defining layer 111 may include third openings 111-OP3a and 111-OP3b respectively overlapping the first trench TR-R and the second trench TR-B. The width of a lower portion of each of the third openings 111-OP3a and 111-OP3b of the subpixel-defining layer 111 may be respectively smaller than the width of an upper portion of each of the first trench TR-R and the second trench TR-B.

Each trench may have an undercut structure. For example, the first trench TR-R and the second trench TR-B may each have an undercut structure.

A portion of the subpixel-defining layer 111 protrudes toward the third opening 111-OP3a of the subpixel-defining layer 111 from a point where a side surface of the second organic insulating layer 109 facing (e.g., defining at least a part of) the first trench TR-R and an upper surface of the second organic insulating layer 109 meet, and may have an undercut structure.

A portion of the subpixel-defining layer 111 protrudes toward the third opening 111-OP3b of the subpixel-defining layer 111 from a point where a side surface of the second organic insulating layer 109 facing (e.g., defining at least a part of) the second trench TR-B and the upper surface of the second organic insulating layer 109 meet.

The common layer 230 may be disposed on the subpixel-defining layer 111. The common layer 230 may include first-1 and first-2 portions 231a and 231b partially overlapping the first and second subpixel electrodes 210a and 210b, respectively. For example, the common layer 230 may include the first-1 portion 231a partially overlapping the first subpixel electrode 210a and the first-2 portion 231b partially overlapping the second subpixel electrode 210b.

A portion of the common layer 230 may be arranged in the first and second trenches TR-R and TR-B. For example, the common layer 230 may include a portion 230-TR-R arranged in the first trench TR-R and a portion 230-TR-B arranged in the second trench TR-B. The portions 230-TR-R and 230-TR-B arranged in the first and second trenches TR-R and TR-B of the common layer 230 may be separated from the first-1 and first-2 portions 231a and 231b by the undercut structure of the first and second trenches TR-R and TR-B.

The opposite electrode 240 may be disposed on the common layer 230. The opposite electrode 240 may include first-1 and first-2 portions 241a and 241b partially overlapping the first and second subpixel electrodes 210a and 210b, respectively.

For example, the opposite electrode 240 may include the first-1 portion 241a partially overlapping the first subpixel electrode 210a and the first-2 portion 241b partially overlapping the second subpixel electrode 210b.

A portion of the opposite electrode 240 may be arranged in the first and second trenches TR-R and TR-B. For example, the opposite electrode 240 may include a portion 240-TR-R arranged in the first trench TR-R and a portion 240-TR-B arranged in the second trench TR-B. The portions 240-TR-R and 240-TR-B arranged in the first and second trenches TR-R and TR-B of the opposite electrode 240 may be separated from the first-1 and first-2 portions 241a and 241b by the undercut structure of the first and second trenches TR-R and TR-B.

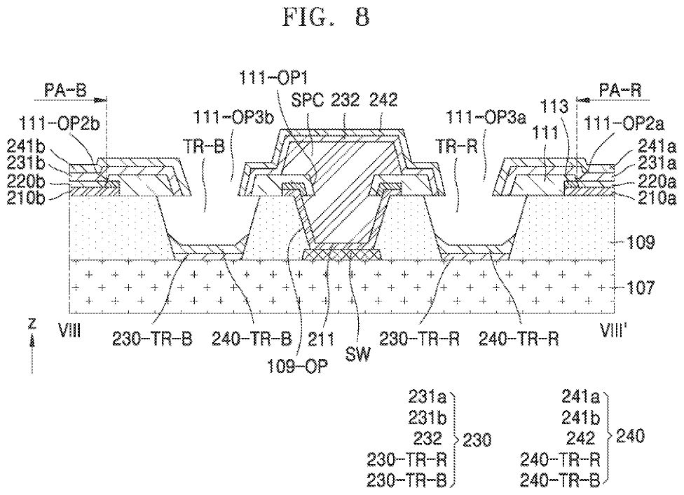

FIG. 8 is a cross-sectional view of the display apparatus taken along line VIII-VIII′ of FIG. 6.

Among features of an embodiment shown in FIG. 8, description of features similar to, or the same as, the features described with reference to FIG. 7 may not be repeated, and differences may be mainly described.

Referring to FIG. 8, the auxiliary wire SW may be disposed on the first organic insulating layer 107. The auxiliary wire SW may be electrically coupled (e.g., electrically connected) with the auxiliary electrode 211. The auxiliary wire SW may provide a common voltage to the auxiliary electrode 211.

The second organic insulating layer 109 may include the hole 109-OP overlapping the auxiliary wire SW and the first and second trenches TR-R and TR-B arranged to be adjacent to the hole 109-OP.

The first trench TR-R and the second trench TR-B may be arranged on opposite sides with respect to the hole 109-OP of the second organic insulating layer 109. For example, the first trench TR-R may be arranged on a right side of the hole 109-OP of the second organic insulating layer 109, and the second trench TR-B may be arranged on a left side of the hole 109-OP of the second organic insulating layer 109.

At least a portion of the auxiliary electrode 211 may be arranged in the hole 109-OP of the second organic insulating layer 109. The auxiliary electrode 211 may be disposed on the second organic insulating layer 109, and a portion of the auxiliary electrode 211 may be in direct contact and thus electrically coupled (e.g., electrically connected) with the auxiliary wire SW in the hole 109-OP of the second organic insulating layer 109. For example, a lower surface of the auxiliary electrode 211 may be in direct contact with an upper surface of the auxiliary wire SW.

The first subpixel electrode 210a and the second subpixel electrode 210b may be disposed on the second organic insulating layer 109. The first subpixel electrode 210a and the second subpixel electrode 210b may be arranged on opposite sides with respect to the hole 109-OP of the second organic insulating layer 109. FIG. 8 illustrates that the first subpixel electrode 210a is arranged on a right side of the hole 109-OP of the second organic insulating layer 109 and the second subpixel electrode 210b is arranged on a left side of the hole 109-OP of the second organic insulating layer 109, but the disclosure is not limited thereto. In another embodiment, the second subpixel electrode 210b may be arranged on the right side of the hole 109-OP of the second organic insulating layer 109, and the first subpixel electrode 210a may be arranged on the left side of the hole 109-OP of the second organic insulating layer 109.

The auxiliary electrode 211, the first subpixel electrode 210a, and the second subpixel electrode 210b may include (e.g., may be) the same material.

The passivation layer 113 may be disposed on the auxiliary electrode 211, the first subpixel electrode 210a, and the second subpixel electrode 210b. The passivation layer 113 may cover an edge region (or edge) of each of the auxiliary electrode 211, the first subpixel electrode 210a, and the second subpixel electrode 210b.

The subpixel-defining layer 111 may be disposed on the second organic insulating layer 109. The subpixel-defining layer 111 may include the first opening 111-OP1 overlapping the auxiliary electrode 211. The first opening 111-OP1 of the subpixel-defining layer 111 may overlap the hole 109-OP of the second organic insulating layer 109.

A portion of the subpixel-defining layer 111 protrudes toward the first opening 111-OP1 of the subpixel-defining layer 111 from a point where a side surface of the second organic insulating layer 109 facing (e.g., defining at least a part of) the hole 109-OP and an upper surface of the second organic insulating layer 109 meet, and may have an undercut structure.

The spacer SPC may be disposed on the auxiliary electrode 211. The spacer SPC may be arranged to overlap the subpixel-defining layer 111, the auxiliary electrode 211, and the hole 109-OP of the second organic insulating layer 109. The spacer SPC may fill a portion of the hole 109-OP of the second organic insulating layer 109, in which the auxiliary electrode 211 is not arranged. The spacer SPC may fill the first opening 111-OP1 of the subpixel-defining layer 111. The spacer SPC may include a side surface tapered with respect to an upper surface of the subpixel-defining layer 111.

The common layer 230 may be disposed on the subpixel-defining layer 111. The common layer 230 may include the first-1 and first-2 portions 231a and 231b partially overlapping the first and second subpixel electrodes 210a and 210b, respectively, and the second portion 232 partially overlapping the auxiliary electrode 211. The second portion 232 of the common layer 230 may be disposed on the spacer SPC and the subpixel-defining layer 111.

The portions 230-TR-R and 230-TR-B respectively arranged in the first and second trenches TR-R and TR-B of the common layer 230 may be separated from the second portion 232 by the undercut structures of the first and second trenches TR-R and TR-B adjacent to the auxiliary electrode 211.

The opposite electrode 240 may be disposed on the common layer 230. The opposite electrode 240 may include first-1 and first-2 portions 241a and 241b partially overlapping the first and second subpixel electrode 210a and 210b, respectively, and the second portion 242 partially overlapping the auxiliary electrode 211. The second portion 242 of the opposite electrode 240 may partially overlap the spacer SPC.

The portions 240-TR-R and 240-TR-B respectively arranged in the first and second trenches TR-R and TR-B of the opposite electrode 240 may be separated from the second portion 242 by the undercut structures of the first and second trenches TR-R and TR-B adjacent to the auxiliary electrode 211.

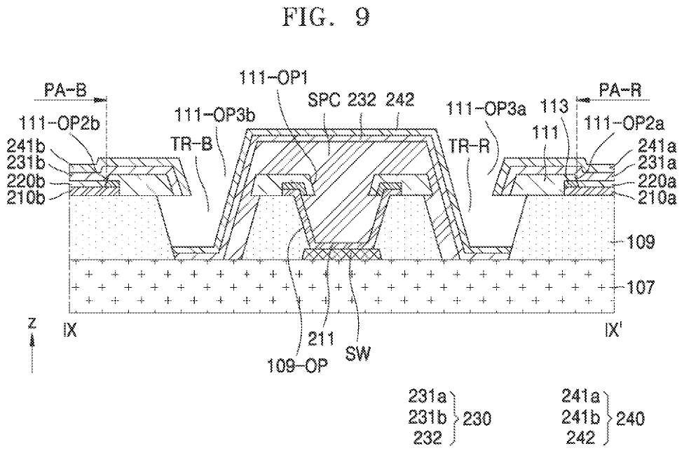

FIG. 9 is a cross-sectional view of the display apparatus taken along line IX-IX′ of FIG. 6.

Among features of an embodiment shown in FIG. 9, description of features similar to, or the same as, the features described with reference to FIGS. 7 and 8 may not be repeated, and differences may be mainly described.

Referring to FIG. 9, the spacer SPC may be arranged to overlap the auxiliary electrode 211, the hole 109-OP of the second organic insulating layer 109, the subpixel-defining layer 111, and portions of the first and second trenches TR-R and TR-B. The spacer SPC may overlap a portion of the undercut structures of the first and second trenches TR-R and TR-B. One side surface of the first trench TR-R may be covered by the spacer SPC. For example, a side surface of the first trench TR-R adjacent to the auxiliary electrode 211 may be covered by the spacer SPC. One side surface of the second trench TR-B may be covered by the spacer SPC. For example, a side surface of the second trench TR-B adjacent to the auxiliary electrode 211 may be covered by the spacer SPC. A side surface of the spacer SPC may be tapered with respect to an upper surface of the first organic insulating layer 107.

A portion of the second portion 232 of the common layer 230 may be arranged in the first trench TR-R. A portion of the second portion 232 of the common layer 230 may be arranged in the second trench TR-B. A portion of the first organic insulating layer 107 exposed by the first trench TR-R and the second trench TR-B may be covered by the spacer SPC and the second portion 232 of the common layer 230.

The first-1 portion 231a and the second portion 232 of the common layer 230 may be separated from each other on one side surface of the first trench TR-R. For example, the first-1 portion 231a and the second portion 232 of the common layer 230 may be separated from each other by the undercut structure of the first trench TR-R on an opposite side of the spacer SPC. The first-2 portion 231b and the second portion 232 of the common layer 230 may be separated from each other on one side surface of the second trench TR-B. For example, the first-2 portion 231b and the second portion 232 of the common layer 230 may be separated from each other by the undercut structure of the second trench TR-B on an opposite side of the spacer SPC.

A portion of the second portion 242 of the opposite electrode 240 may be arranged in the first trench TR-R. A portion of the second portion 242 of the opposite electrode 240 may be arranged in the second trench TR-B.

The first-1 portion 241a and the second portion 242 of the opposite electrode 240 may be separated from each other on one side surface of the first trench TR-R. For example, the first-1 portion 241a and the second portion 242 of the opposite electrode 240 may be separated from each other by the undercut structure of the first trench TR-R on the opposite side of the spacer SPC. The first-2 portion 241b and the second portion 242 of the opposite electrode 240 may be separated from each other on one side surface of the second trench TR-B. For example, the first-2 portion 241b and the second portion 242 of the opposite electrode 240 may be separated from each other by the undercut structure of the second trench TR-B on the opposite side of the spacer SPC.

FIG. 9 illustrates that the spacer SPC overlaps the first trench TR-R and the second trench TR-B, but the disclosure is not limited thereto. In another embodiment, the spacer SPC may overlap one of the first trench TR-R or the second trench TR-B. For example, the spacer SPC may overlap the first trench TR-R but not overlap the second trench TR-B, or the spacer SPC may overlap the second trench TR-B but not overlap the first trench TR-R.

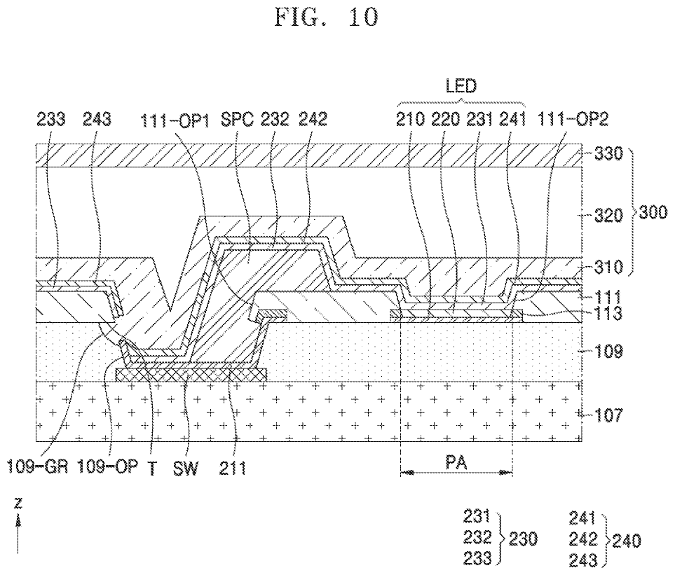

FIG. 10 is a cross-sectional view of a portion of a display apparatus according to an embodiment.

Among features of an embodiment shown in FIG. 10, description of features similar to, or the same as, the features described with reference to FIG. 4 may not be repeated, and differences may be mainly described.

The second organic insulating layer 109 may further include a recess 109-GR located in a side surface of the second organic insulating layer 109 on an opposite side of the spacer SPC. The auxiliary electrode 211 may cover a portion of the side surface of the second organic insulating layer 109 in which the recess 109-GR is arranged. In some embodiments, the auxiliary electrode 211 does not cover the recess 109-GR. In some embodiments, the portion of the side surface of the second organic insulating layer 109 in which the recess 109-GR is formed may be exposed.

The tip T of the subpixel-defining layer 111 may be disposed above the recess 109-GR. The auxiliary electrode 211 and/or the passivation layer 113 may not be arranged between the tip T of the subpixel-defining layer 111 and the recess 109-GR.

The second portion 232 and the third portion 233 of the common layer 230 may be separated from each other by the tip T on the recess 109-GR. In some embodiments, in a process for depositing the common layer 230, the second portion 232 and the third portion 233 of the common layer 230 may not be connected with each other due to the recess 109-GR, and may be separated and apart from each other (e.g., by the recess 109-GR).

The second portion 242 and the third portion 243 of the opposite electrode 240 may be separated from each other by the tip T on the recess 109-GR. In some embodiments, in a process for depositing the opposite electrode 240 during a manufacturing process, the second portion 242 and the third portion 243 of the opposite electrode 240 may not be connected with each other due to the recess 109-GR, and may be separated and apart from each other.

The second portion 242 of the opposite electrode 240 may be in direct contact with the auxiliary electrode 211 located on the opposite side of the spacer SPC. In some embodiments, a material forming the opposite electrode 240 may be deposited in a direction oblique to a direction (for example, z direction) normal (e.g., perpendicular) to a substrate, and accordingly, the second portion 242 of the opposite electrode 240 may further extend beyond an edge of the second portion 232 of the common layer 230 and may be in direct contact with a portion of the auxiliary electrode 211. A contact region between a portion of the opposite electrode 240 and a portion of the auxiliary electrode 211 may be disposed near the recess 109-GR, for example, under the recess 109-GR.

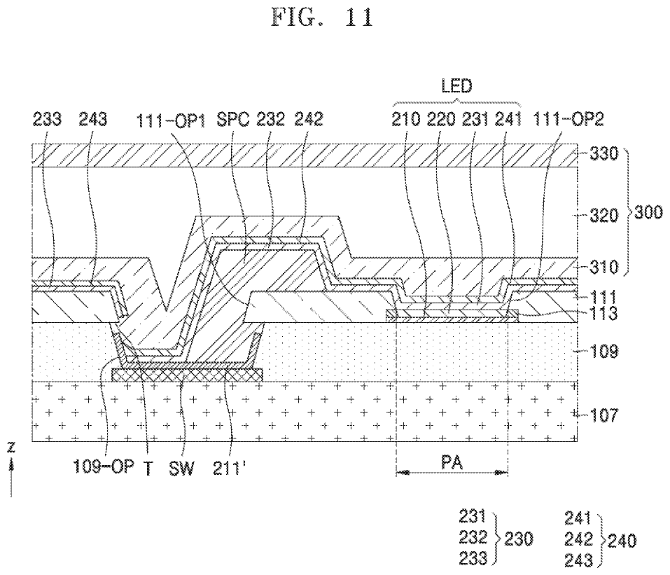

FIG. 11 is a cross-sectional view of a portion of a display apparatus according to an embodiment.

Among features of an embodiment shown in FIG. 11, description of features similar to, or the same as, the features described with reference to FIG. 4 may not be repeated, and differences may be mainly described.

Referring to FIG. 11, an auxiliary electrode 211′ may be arranged in the hole 109-OP of the second organic insulating layer 109. There may be a portion of a side surface of the second organic insulating layer 109, which is not covered by the auxiliary electrode 211′ and exposed. For example, the auxiliary electrode 211′ may cover only part (e.g., a lower part) of a side surface of the second organic insulating layer 109 that defines at least part of the hole 109-OP.

The passivation layer 113 may not be arranged between a portion of the second organic insulating layer 109 adjacent to the hole 109-OP and the subpixel-defining layer 111. In some embodiments, the passivation layer 113 may be formed on an edge region (or edge) of the subpixel electrode 210.

The auxiliary electrode 211′ may include (e.g., may be) a material different from that of the subpixel electrode 210. For example, the auxiliary electrode 211′ may include (e.g., may be) at least one material that may form the subpixel electrode 210 described above with reference to FIG. 3 and may be formed as a single layer or a multilayer. In some embodiments, the auxiliary electrode 211′ may be formed in a separate operation by utilizing (e.g., using) a material separate from that of the subpixel electrode 210 during a manufacturing process.

The second portion 232 and the third portion 233 of the common layer 230 may be separated from each other on an opposite side of the spacer SPC. In some embodiments, in a process for depositing the common layer 230, the second portion 232 and the third portion 233 of the common layer 230 may not be connected with each other due to a structure in which the tip T and the auxiliary electrode 211′ are apart from each other, and may be separated and apart from each other.

The second portion 242 and the third portion 243 of the opposite electrode 240 may be separated from each other on the opposite side of the spacer SPC. In some embodiments, in a process for depositing the opposite electrode 240, the second portion 242 and the third portion 243 of the opposite electrode 240 may not be connected with each other due to a structure in which the tip T and the auxiliary electrode 211′ are apart from each other, and may be separated and apart from each other.

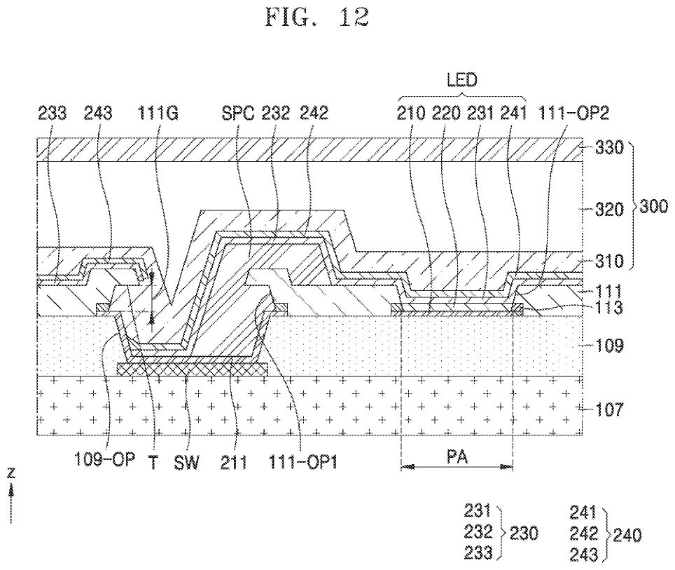

FIG. 12 is a cross-sectional view of a portion of a display apparatus according to an embodiment.

Among features of an embodiment shown in FIG. 12, description of features similar to, or the same as, the features described with reference to FIG. 4 may not be repeated, and differences may be mainly described.

Referring to FIG. 12, a portion of the subpixel-defining layer 111 corresponding to the tip T may further include a step difference 111-G with respect to another portion of the subpixel-defining layer 111, which is adjacent thereto. For example, the subpixel-defining layer 111 may have a step shape at the tip T. In some embodiments, the height from an upper surface of the first organic insulating layer 107 in a normal (e.g., perpendicular) direction (for example, z direction) to an upper surface of the portion of the subpixel-defining layer 111 may be different from the height from the upper surface of the first organic insulating layer 107 to an upper surface of the other portion of the subpixel-defining layer 111.

The step difference 111-G of the subpixel-defining layer 111 may be implemented by utilizing (e.g., using) a sacrificial layer in a manufacturing process. For example, the step difference 111-G may be implemented by, before arranging the subpixel-defining layer 111, arranging a sacrificial layer arranged in the hole 109-OP of the second organic insulating layer 109 and protruding from an upper surface of the hole 109-OP, arranging the subpixel-defining layer 111 to overlap a portion of the sacrificial layer, and then removing the sacrificial layer.

The second portion 232 and the third portion 233 of the common layer 230 may be separated from each other on an opposite side of the spacer SPC. In some embodiments, in a process for depositing the common layer 230, the second portion 232 and the third portion 233 of the common layer 230 may not be connected with each other due to the step difference 111-G, and may be separated and apart from each other.

The second portion 242 and the third portion 243 of the opposite electrode 240 may be separated from each other on the opposite side of the spacer SPC. In some embodiments, in a process for depositing the opposite electrode 240, the second portion 242 and the third portion 243 of the opposite electrode 240 may not be connected with each other due to the step difference 111-G, and may be separated and apart from each other.

According to an embodiment, a display apparatus, in which a cathode electrode may be in contact with an auxiliary electrode so as to be coupled (e.g., connected) to a current source, in a central region of the display apparatus, may be implemented. A method of substantially equally distributing a current to an outer region and to a central region of a display apparatus may be desired, and one or more embodiments of the present disclosure provide such a method. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various suitable changes in form and details may be made therein without departing from the spirit and scope as defined by the following claims and equivalents thereof.

What is claimed is:

1. A display apparatus comprising:
a substrate;
an organic insulating layer on the substrate and having a hole;
a subpixel electrode on the organic insulating layer;
an auxiliary electrode comprising at least a portion arranged in the hole of the organic insulating layer;
a subpixel-defining layer on the organic insulating layer and having a first opening overlapping the auxiliary electrode and a second opening overlapping the subpixel electrode;
an emission layer on the subpixel electrode;
an opposite electrode on the emission layer;
a common layer arranged between the subpixel electrode and the opposite electrode and extending onto the subpixel-defining layer to overlap the subpixel-defining layer; and
a spacer below the common layer and overlapping a portion of the auxiliary electrode, a portion of the hole of the organic insulating layer, and a portion of the subpixel-defining layer.

2. The display apparatus of claim 1, further comprising an auxiliary wire below the organic insulating layer and electrically coupled with the auxiliary electrode.

3. The display apparatus of claim 1, wherein the auxiliary electrode and the subpixel electrode comprise a same material.

4. The display apparatus of claim 1, wherein the subpixel-defining layer comprises a tip protruding toward the first opening.

5. The display apparatus of claim 4, wherein the spacer covers a portion of the tip and comprises a side surface tapered with respect to an upper surface of the auxiliary electrode.

6. The display apparatus of claim 5, wherein the common layer comprises separate portions around another portion of the tip on an opposite side of the hole from the spacer.

7. The display apparatus of claim 6, wherein one of the separate portions of the common layer is in direct contact with a portion of the auxiliary electrode.

8. The display apparatus of claim 5, wherein the opposite electrode comprises separate portions around another portion of the tip on an opposite side of the hole from the spacer.

9. The display apparatus of claim 8, wherein one of the separate portions of the opposite electrode is in direct contact with a portion of the auxiliary electrode, around the other portion of the tip.

10. The display apparatus of claim 5, wherein the side surface of the spacer forms an inclination angle of 30 degrees to 60 degrees with respect to the upper surface of the auxiliary electrode.

11. The display apparatus of claim 4, wherein the organic insulating layer further comprises a recess under the tip on an opposite side of the hole from the spacer, and recessed with respect to a side surface of the organic insulating layer.

12. The display apparatus of claim 4, wherein an upper surface of a portion of the subpixel-defining layer comprising the tip has a step difference with respect to an upper surface of another portion of the subpixel-defining layer on an upper surface of the organic insulating layer.

13. The display apparatus of claim 1, wherein the subpixel-defining layer comprises an inorganic insulating material.

14. The display apparatus of claim 1, wherein the spacer comprises an organic insulating material.

15. A method of manufacturing a display apparatus, the method comprising:
forming a substrate;
forming, on the substrate, an organic insulating layer having a hole;
forming a subpixel electrode on the organic insulating layer;
forming an auxiliary electrode comprising at least a portion arranged in the hole of the organic insulating layer;
forming, on the organic insulating layer, a subpixel-defining layer having a first opening overlapping the auxiliary electrode and a second opening overlapping the subpixel electrode;
forming a spacer overlapping a portion of the auxiliary electrode, a portion of the hole of the organic insulating layer, and a portion of the subpixel-defining layer;
forming, on the subpixel electrode, an intermediate layer comprising an emission layer and a common layer; and
forming an opposite electrode on the intermediate layer.

16. The method of claim 15, wherein the forming of the subpixel-defining layer comprises forming a tip protruding toward the first opening from a point where an upper surface of the organic insulating layer and a side surface of the organic insulating layer facing the hole meet.

17. The method of claim 16, wherein, in the forming of the spacer, a portion of the spacer overlaps a portion of the tip, and a side surface of the spacer is tapered with respect to an upper surface of the auxiliary electrode.

18. The method of claim 17, wherein, in the forming of the common layer, the common layer comprises separate portions around another portion of the tip on an opposite side of the hole from the spacer, and
In the forming of the opposite electrode, the opposite electrode comprises separate portions around the other portion of the tip on the opposite side of the hole from the spacer.

19. The method of claim 16, wherein the forming of the organic insulating layer comprises forming a recess under the tip located on an opposite side of the hole from the spacer.

20. The method of claim 15, wherein the forming of the subpixel-defining layer comprises:
forming, on the organic insulating layer, a sacrificial layer to overlap the auxiliary electrode;
forming the subpixel-defining layer to overlap a portion of the sacrificial layer; and
removing the sacrificial layer.
